(19) United States
(12) Patent Application Publication
(10) Pub. No.: US 2009/0315141 A1
(43) Pub. Date: Dec. 24, 2009

(54) ISOLATION LAYER OF SEMICONDUCTOR DEVICE AND MANUFACTURING METHOD THEREOF

(76) Inventor: Ki-Moon Jung, Gwanek-gu (KR)

Correspondence Address: SHERR & VAUGHN, PLLC, 620 HERNDON PARKWAY, SUITE 320, HERNDON, VA, 20170, US

(21) Appl. No.: 12/487,540

(22) Filed: Jun. 18, 2009

(30) Foreign Application Priority Data
Jun. 20, 2008 (KR) 10-2008-0058126

(51) Int. Cl. H01L 29/06; H01L 21/762

(52) U.S. Cl. 257/510; 438/424; 257/E21.546; 257/E29.018

(57) ABSTRACT

An isolation layer of a semiconductor device, and a method of manufacturing the same, may include a trench formed in a semiconductor substrate, a first liner protective layer formed along an inner surface of the trench, a low-K material pattern formed over the first liner protective layer filling the trench, a recess formed over the low-K material pattern such that an upper sidewall of the first liner protective layer is exposed, and a second liner protective layer formed in the recess preventing the low-K material pattern from being exposed.

The present application claims priority under 35 U.S.C. 119 to Korean Patent Application No. 10-2008-0058126 (filed on Jun. 20, 2008), which is hereby incorporated by reference in its entirety.

### BACKGROUND

The present invention relates to an isolation layer of a semiconductor device and a method for manufacturing the same.

An isolation layer may be formed over a semiconductor substrate to isolate devices, through a semiconductor process, by forming an insulating layer between the devices. A shallow trench isolation (STI) technology may be adopted in a semiconductor isolation process, wherein a trench is formed in the semiconductor substrate and an insulating material, such as an oxide, is filled therein. The result is a reduced field area size within a trench, such that a semiconductor device may be fabricated at a micro size.

However, because semiconductor devices have become highly integrated, a width of a trench becomes narrowed and the resulting capacitance of a trench is a drawback. Particularly, an insulating material such as an oxide layer is filled in the trench such that a parasitic capacitance is inevitably generated. Also, resistance-capacitance (RC) delay is induced, and performance of the semiconductor device may be degraded.

### SUMMARY

According to embodiments, an isolation layer of a semiconductor device and a method for manufacturing the same may reduce capacitance of an isolation layer and may improve insulation properties of an isolation layer. In embodiments, an isolation layer of a semiconductor device includes a trench formed in a semiconductor substrate, and a low-K material pattern formed in a trench.

In embodiments, a method for manufacturing an isolation layer of a semiconductor device includes forming a pad nitride layer pattern on a semiconductor substrate, forming a trench by etching a semiconductor substrate using a pad nitride layer pattern as an etch mask, and forming a low-K material pattern in a trench.

### DRAWINGS

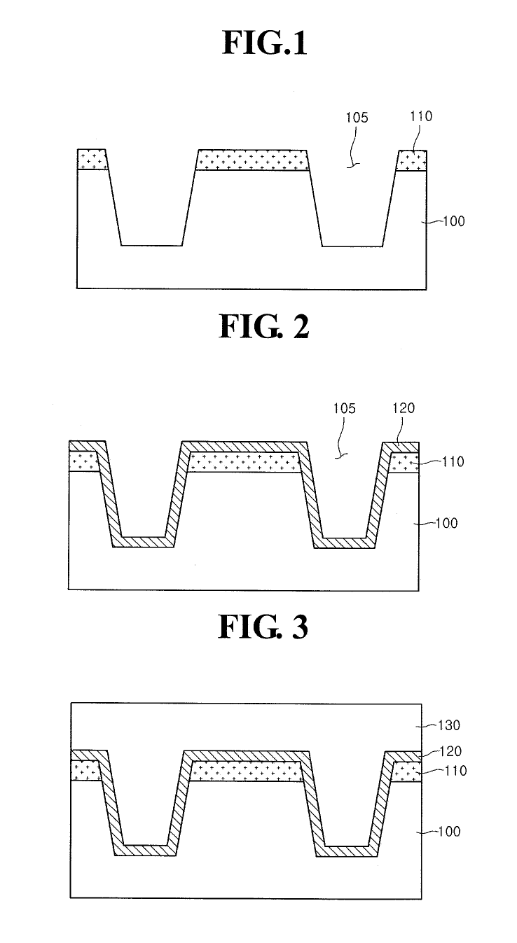

Examples FIG. 1 to FIG. 7 are schematic cross sectional views showing steps of fabricating an isolation layer of a semiconductor device according to embodiments.

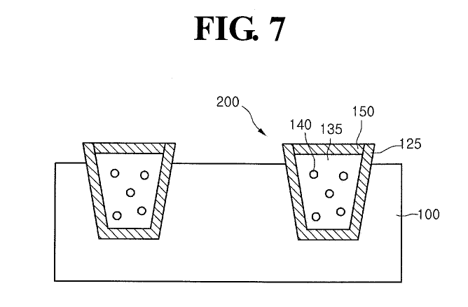

Example FIG. 7 shows a cross sectional view of an isolation layer of a semiconductor device according to embodiments.

### DESCRIPTION

Hereinafter, embodiments will be described with reference to the accompany drawings. Referring to example FIG. 7, a cross sectional view illustrating an isolation layer of a semiconductor is shown. An isolation layer may include a trench 105 formed in a semiconductor substrate 100, as shown in example FIG. 1. As shown in example FIG. 7, isolation layer 200 may include a first liner protective layer 125 formed in the trench 105 and a low-K material pattern 135 formed over the first liner protective layer 125 filling the trench 105. As shown in example FIG. 5, a recess 107 may be formed over the low-K material pattern 135 such that an upper sidewall of the first liner protective layer 125 is exposed. Referring back to example FIG. 7, an isolation layer 200 may include a second liner protective layer 150 formed in the recess 107 preventing the low-K material pattern 135 from being exposed.

In embodiments a low-K material pattern, such as the low-K material pattern 135, may include low-K material having a relatively low dielectric constant K from approximately 1.4 to approximately 4.0. For example, the low-K material pattern 135 may include low-K material such as fluorine-doped silica glass (FSG) or an oxide of silicon, such as Si O—C—H. In embodiments an isolation layer, such as the isolation layer 200 may include pores 140 disposed therein. Thus, a dielectric constant K of the isolation layer 200 may be relatively low, such that parasitic capacitance may be reduced. In embodiments protective layers, such as the first and the second liner protective layers 125 and 150, respectively, may include an oxide layer. Thus, the relatively low mechanical strength of a low-K material pattern, such as the low-K material pattern 135, may be reinforced.

According to embodiments, steps of fabricating an isolation layer of a semiconductor device are shown and described with reference to examples FIGS. 1 to 7. Referring to example FIG. 1, a trench 105 is formed in a semiconductor substrate 100. In embodiments, a pad nitride layer 110 may be formed over a portion or over the whole area of the semiconductor substrate 100 and a photoresist layer may be formed over the pad nitride layer 110. An exposure and a development process may be applied to the photoresist layer such that a predetermined area of the photoresist layer, corresponding for example to a trench area, may be selectively removed to form a photoresist pattern. The pad nitride layer 110 and the semiconductor substrate 100 may be etched by using the photoresist pattern as an etch mask, thereby forming the trench 105. According to embodiments, before forming the pad nitride layer 110, a pad oxide layer may be selectively formed over the semiconductor substrate 100 to prevent the semiconductor substrate 100 from being stressed by the pad nitride layer 110.

Referring to FIG. 2, a first liner protective layer 120 may be formed on the semiconductor substrate 100 which may include the pad nitride layer 110 and the trench 105. In embodiments, the first liner protective layer 120 may include an oxide layer, such as SiO₂, that may have a relatively thin thickness which may be formed along the inner surface of the trench 105. The first liner protective layer 120 may be formed along the inner surface of the trench 105 to reinforce the mechanical strength of the trench gap-fill material. The first liner protective layer 120 may prevent the direct application of stress to the trench 105 when, for example, an insulating material which may fill the trench 105 is deposited therein. The first liner protective layer 120 may prevent non-uniformity resulting from a deposition rate and/or by property differences between the semiconductor substrate 100, which may be exposed through the trench 105, and for example the pad nitride layer 110.

Referring to FIG. 3, low-K materials such as low-K materials 130 may gap-fill the trench 105, which may include the first liner protective layer 120. The low-K materials 130 may cover a portion or the entire surface of the semiconductor substrate 100 including the trench 105. In embodiments, the low-K materials 130 may have a dielectric constant K from approximately 1.4 to approximately 4.0. According to embodiments, the low-K materials 130 may be formed by depositing material such as FSG or Si O—C—H through a high density plasma chemical vapor deposition (HDP-CVD) process. In embodiments, the low-K materials 130 may be filled in the trench 105 to form an isolation layer, such that parasitic capacitance may be reduced by, for example, the low dielectric constant of the low-K materials 130.

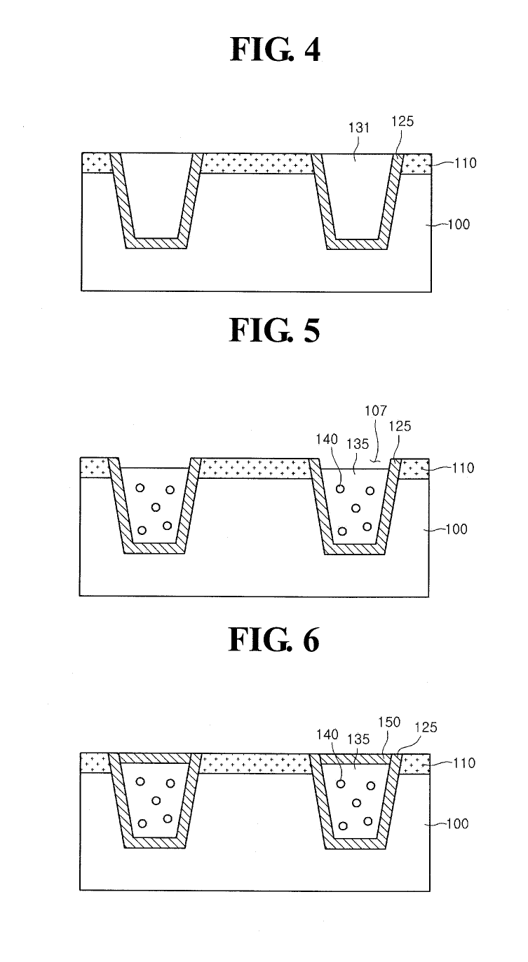

Referring to FIG. 4, the low-K materials 130 may be subject to a planarization process such that a low-K material pattern 131 may be formed, for example, only in the trench 105. In embodiments, the low-K materials 130 may be planarized through a chemical mechanical polishing (CMP) process and the pad nitride layer 110 may be used as a polishing end point. According to embodiments, when the low-K material pattern 131 is formed, the first liner protective layer 125 formed over an area other than the trench 105 may be removed. Thus, the first liner protective layer 125 patterned in the trench 105 may remain. In embodiments, the low-K material pattern 131 may gap-fill the trench 105 and may be level with the pad nitride layer 110. The first liner protective layer 125 may be formed along the inner surface of the trench 105 to protect the periphery of the low-K material pattern 131.

Referring to FIG. 5, the low-K material pattern 131 may be subject to a heat treatment process, such that the low-K material pattern 135 may be formed having the pores 140 disposed therein. In embodiments, the heat treatment process for the low-K material pattern 131 may be performed by using N₂ gas such that chemical reaction may not occur with respect to the insulating material. According to embodiments, the heat treatment process for the low-K material pattern 131 may be performed such that the pores 140 formed in the low-K material pattern 131 results in a greatly reduced dielectric constant. In embodiments, the pores 140 may be formed so the mechanical strength of the low-K material pattern 135 can be comparatively lowered. According to embodiments, the heat treatment process for the low-K material pattern 131 may be performed such that the thickness of the low-K material pattern 131 may be reduced by approximately 5% to approximately 15% due to internal stress. In embodiments, the height of the low-K material pattern 131 may be lower than the height of the pad nitride layer 110 such that a step difference occurs between the low-K material pattern 131 and the pad nitride layer 110. Hereinafter, the exposed trench 105 disposed over the low-K material pattern 135, which may be formed by the step difference, will be referred to as the recess 107. In embodiments, an upper surface of the low-K material pattern 131 and an upper side surface of the first liner protective layer 125 may be exposed through the recess 107.

Referring to FIG. 6, the second liner protective layer 150 may be formed over the low-K material pattern 135 to fill the recess 107. In embodiments, the second liner protective layer 150 may include an oxide layer, such as SiO₂, which is substantially similar to the first liner protective layer 125. According to embodiments, the second liner protective layer 150 may fill the recess 107 and may protect the low-K material pattern 135. In embodiments, the first liner protective layer 125 may be formed along the inner surface of the trench 105 and the second liner protective layer 150 may be formed over the low-K material pattern 135 such that the second liner protective layer 150 may be connected to the first liner protective layer 125. The outer surface of the low-K material pattern 135 may be protected by, for example, the connection of the first and second liner protective layers 125 and 150. Also, since the first and the second liner protective layers 125 and 150, respectively, may include an oxide layer and may have high mechanical strength, the first and the second liner protective layers 125 and 150, respectively, may reinforce the low-K material pattern 135 having relative low mechanical strength such that the low-K material pattern 135 may maintain a stable state.

Referring to FIG. 7, the pad nitride layer 110 may be removed such that the isolation layer 200 may be formed on the semiconductor substrate 100. As described above, an isolation layer according to embodiments may include low-K materials and may include pores therein such that the dielectric constant of an isolation layer may be lowered. In embodiments, parasitic capacitance of an isolation layer may be reduced and RC delay may be reduced. Consequently, device performance may be substantially improved. In embodiments, a protective layer may include an oxide layer and may be formed in the peripheral area of an isolation layer such that the mechanical strength of an isolation layer may be reinforced.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a trench formed in a semiconductor substrate; and
a low-K material pattern formed in the trench.

2. The apparatus of claim 1, comprising a liner protective layer surrounding an outer surface of the low-K material pattern.

3. The apparatus of claim 2, wherein the liner protective layer comprises:
a first liner protective layer formed along an inner surface of the trench;
a recess formed above the low-K material pattern such that an upper sidewall of the first liner protective layer is exposed; and
a second liner protective layer formed in the recess.

4. The apparatus of claim 3, wherein at least one of the first and the second liner protective layers includes an oxide layer.

5. The apparatus of claim 1, wherein the low-K material pattern comprises a pore.

6. The apparatus of claim 1, wherein the low-K material pattern includes material having a dielectric constant K from approximately 1.4 to approximately 4.0.

7. A method comprising:
forming a pad nitride layer pattern over a semiconductor substrate;
forming a trench in the semiconductor substrate; and
forming a low-K material pattern in the trench.

8. The method of claim 7, comprising forming a pad oxide layer over the semiconductor substrate.

9. The method of claim 7, wherein the pad nitride layer pattern is formed over an entire surface of the semiconductor substrate.

10. The method of claim 7, wherein the trench is formed by etching the semiconductor substrate using the pad nitride layer pattern as an etch mask.

11. The method of claim 7, comprising forming a first liner protective layer in the trench.

12. The method of claim 7, comprising:
performing a heat treatment process with respect to the low-K material pattern; and
forming a recess above the low-K material pattern.

13. The method of claim 12, comprising forming a first liner protective layer in the trench and a second liner protective layer in the recess.

14. The method of claim 12, wherein a pore is formed in the low-K material pattern.

15. The method of claim 12, wherein N₂ gas is used during an annealing process.

16. The method of claim 7, wherein the low-K material pattern includes material having a dielectric constant K from approximately 1.4 to approximately 4.0.

17. A method comprising:
forming a pad nitride layer pattern over a semiconductor substrate;
forming a trench by etching the semiconductor substrate using the pad nitride layer pattern as an etch mask;
forming a first liner protective layer in the trench;
forming a low-K material pattern over the first liner protective layer to fill the trench;
forming a recess above the low-K material pattern by performing a heat treatment process with respect to the low-K material pattern; and
forming a second liner protective layer in the recess.

18. The method of claim 17, wherein a pore is formed in the low-K material pattern.

19. The method of claim 18, wherein the pore is formed when the heat treatment process is performed with respect to the low-K material pattern.

20. The method of claim 17, wherein the low-K material comprises at least one of a flurosilicate glass and an oxide of silicon.
